(19) United States
(12) Patent Application Publication
(10) Pub. No.: US 2025/0068804 A1
(43) Pub. Date: Feb. 27, 2025

(54) METHODS AND SYSTEMS FOR LARGE-SCALE RESERVOIR SIMULATIONS USING AUTOMATED LOCAL GRID REFINEMENT

(71) Applicant: ARAMCO SERVICES COMPANY, Houston, TX (US)

(72) Inventors: Yashod Savithru Jayasinghe, Framingham, MA (US); Eric A. Dow, Boston, MA (US)

(73) Assignee: ARAMCO SERVICES COMPANY, Houston, TX (US)

(21) Appl. No.: 18/456,394

(22) Filed: Aug. 25, 2023

(51) Int. Cl. G06F 30/28

(52) U.S. Cl. CPC G06F 30/28; E21B 43/25; E21B 44/00; E21B 2200/20

(57) ABSTRACT

Method and systems for generating a reservoir simulation grid for a subterranean reservoir are disclosed. The method may include, using a reservoir simulation system, to obtain a reservoir model, where the reservoir model comprises a plurality of wellbore trajectories, define a coarse simulation grid pertaining to, at least a portion, of the reservoir model, and determine a grid refinement field based, at least in part, on the reservoir model. The method may further include, using a reservoir simulation system, to form a tree based on the coarse simulation grid, refine the tree at least in part, on an intersection of the grid refinement field and the coarse simulation grid, and define the reservoir simulation grid based, at least in part, on the refined tree and the coarse simulation grid.

### BACKGROUND

Reservoir simulation models play an important role in managing hydrocarbon resources in productive geological regions. In particular, a reservoir simulation model may be used to predict future oil, water, and gas production rates from a well in an oil and gas reservoir. For example, the location of a new well site at the hydrocarbon reservoir, a fluid injection plan, or the design of production equipment for the well may be guided by reservoir simulations. Reservoir simulation models are typically composed of hundreds or thousands, or millions of cells that provide a discretized numerical representation of the reservoir. Reservoir simulation models are often iteratively modified to obtain a satisfactory match with measured production rates in historical wells to validate the fidelity of the reservoir simulation model. Such modifications may include changes, including spatially variable changes, in the sizes of the cells from which the reservoir simulation model is composed.

Local grid refinement (LGR) is a technique used to improve the accuracy of grid-based reservoir simulations, where a subset of grid cells is refined to obtain a better spatial resolution, particularly in regions of interest, such as near wellbore, or near group or fracture or casing perforations often distributed at discrete locations along a wellbore. In contrast to global grid refinement approaches, where all grid cells are refined, local grid refinement offers an attractive trade-off between solution accuracy and computational costs of the reservoir simulation.

Recently, LGR methods have been applied in reservoir simulation to target the near-wellbore regions of the reservoir because the accuracy with which the physics of fluid percolation in these regions is simulated has an outsized impact on the overall accuracy of the reservoir simulation. The presence of higher fluid percolation velocities (“Darcy velocities”) and complex phase behaviors, such as outgassing in oil reservoirs or the formation of condensates in gas reservoirs, and the reservoir heterogeneities, such as natural or hydraulic fractures or geological faults, warrant the use of smaller grid cells.

Despite the apparent advantages of LGRs, a survey of the prior art shows that they are typically used only to study the flow physics around an isolated or small number of wells. The large-scale LGR applications in reservoir simulation containing dozens or hundreds of wells, even after the significant growth of available computational power in recent years, suggests that additional factors may limit the widespread application of LGR methods to practical scale reservoir problems. One such factor is the difficulty of designing the local grids appropriate for a given reservoir problem.

Real-world large-scale reservoir models typically contain hundreds of densely-spaced vertical and lateral wells in complex configurations and trajectories, including with multiple branches in each well. The process of manually designing LGRs for such models becomes extremely cumbersome and practically infeasible. Typically, it is not feasible for a simulation engineer to manually design LGRs for such realistic cases. Instead, manual designs typically produce at most a few dozen LGRs that cover large portions of the grid, including large regions that do not require refinement. As a result, the subsequent reservoir simulations can be significantly more computationally intensive due to the unnecessary grid refinement.

An alternative approach for refining irregularly-shaped regions of the grid is to define an LGR for each cell on the original grid that needs to be refined. This method is similar to the tree-based refinement techniques used in several dynamic grid refinement works (Sammon 2003, Babaei et al. 2013, Gonzalez 2016). Although this approach ensures that the target region is covered exactly without any over-refinement of nearby regions, the method becomes impractical for large scale problems since the number of local grids scales proportionally with the number of original grid cells in the targeted refinement region. Simulation cases with tens of thousands of small LGRs, each covering a small region of the original grid, tend to have slower input/output times, produce larger intermediate and output files, and are generally more difficult to visualize and postprocess using existing commercial visualization software compared to simulations with fewer LGRs (but containing a similar number of active cells).

Consequently, there is a pressing need for an automated computer-based method that eliminates or minimizes manual intervention to generate complex grids in a large-scale reservoir simulation. Such a method should produce a validated set of nonoverlapping LGRs that eliminates, or minimizes the amount of, unnecessary grid refinement and yields a minimum grid complexity required to obtain a desired simulation accuracy.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In general, in one aspect, embodiments relate to methods of generating a reservoir simulation grid for a subterranean reservoir. The methods may include, using a reservoir simulation system, to obtain a reservoir model, where the reservoir model comprises a plurality of wellbore trajectories, define a coarse simulation grid pertaining to, at least a portion, of the reservoir model, and determine a grid refinement field based, at least in part, on the reservoir model. The method may further include, using a reservoir simulation system, to form a tree based on the coarse simulation grid, refine the tree at least in part, on an intersection of the grid refinement field and the coarse simulation grid, and define the reservoir simulation grid based, at least in part, on the refined tree and the coarse simulation grid.

In general, in one aspect, embodiments relate to systems, including a reservoir model pertaining to a subterranean reservoir, wherein the reservoir model comprises a plurality of wellbore trajectories, and a reservoir simulation system. The reservoir simulation system is configured to receive the reservoir model, define a coarse simulation grid pertaining to, at least a portion, of the reservoir model, and determine a grid refinement field based, at least in part, on the reservoir model. The reservoir simulation system is further configured to form a tree based on the coarse simulation grid, refine the tree at least in part, on an intersection of the grid refinement field and the coarse simulation grid, and define the reservoir simulation grid based, at least in part, on the refined tree and the coarse simulation grid.

Other aspects and advantages of the claimed subject matter will be apparent from the following description and the appended claims.

### BRIEF DESCRIPTION OF DRAWINGS

Specific embodiments of the disclosed technology will now be described in detail with reference to the accompanying figures. Like elements in the various figures are denoted by like reference numerals for consistency.

FIG. 1 illustrates a hydrocarbon reservoir and reservoir simulation model in accordance with one or more embodiments.

FIG. 2 depicts a flowchart in accordance with one or more embodiments.

FIG. 3 depicts reservoir simulation grids in accordance with one or more embodiments.

FIG. 4 depicts an octree in accordance with one or more embodiments.

FIG. 5 shows a flowchart in accordance with one or more embodiments.

FIG. 6 shows computer software in accordance with one or more embodiments.

FIGS. 7A-7D depict a quadtree in accordance with one or more embodiments.

FIGS. 8A-8G depict a quadtree in accordance with one or more embodiments.

FIGS. 9A-9E depict a quadtree in accordance with one or more embodiments.

FIG. 10 shows computer software in accordance with one or more embodiments.

FIG. 11 shows a flowchart in accordance with one or more embodiments.

FIGS. 12A-12D show reservoir simulation grids in accordance with one or more embodiments.

FIG. 13 shows a reservoir simulation grid in accordance with one or more embodiments.

FIGS. 14A-14B show performance curves in accordance with one or more embodiments.

FIG. 15 shows performance statistics in accordance with one or more embodiments.

FIG. 16 shows a drilling system in accordance with one or more embodiments.

FIG. 17 shows a computer system in accordance with one or more embodiments.

### DETAILED DESCRIPTION

Specific embodiments of the disclosure will now be described in detail with reference to the accompanying figures. Like elements in the various figures are denoted by like reference numerals for consistency.

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as using the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

It is to be understood that the singular forms “a,” “an,” and “the” include plural referents unless the context clearly dictates otherwise. Thus, for example, reference to “cell” includes reference to one or more of such cells.

Terms such as “approximately,” “substantially,” etc., mean that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

It is to be understood that one or more of the steps shown in the flowchart may be omitted, repeated, and/or performed in a different order than the order shown. Accordingly, the scope disclosed herein should not be considered limited to the specific arrangement of steps shown in the flowchart.

Although multiple dependent claims are not introduced, it would be apparent to one of ordinary skill that the subject matter of the dependent claims of one or more embodiments may be combined with other dependent claims.

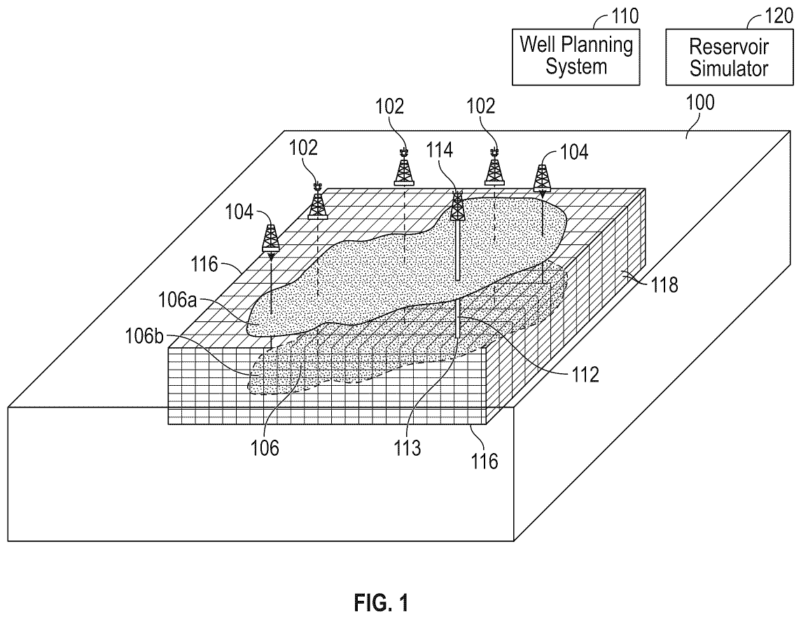

In the following description of FIGS. 1-X, any component described with regard to a figure, in various embodiments disclosed herein, may be equivalent to one or more like-named components described with regard to any other figure. For brevity, descriptions of these components will not be repeated with regard to each figure. Thus, each and every embodiment of the components of each figure is incorporated by reference and assumed to be optionally present within every other figure having one or more like-named components. Additionally, in accordance with various embodiments disclosed herein, any description of the components of a figure is to be interpreted as an optional embodiment which may be implemented in addition to, in conjunction with, or in place of the embodiments described with regard to a corresponding like-named component in any other figure.

Reservoir simulation plays an important role in planning and managing a hydrocarbon reservoir. Simulation typically involves representing the properties (e.g., rock porosity and permeability, and pore fluid pressure) of the reservoir on a grid of points. In an initial stage, termed “history matching”, past (“historic”) production, i.e., flow rates and downhole pressures, may be simulated and reservoir properties adjusted, iteratively, until simulated values match the historic measured values of flow rates and downhole pressures. In a second predictive phase, the behavior of the reservoir, including pore fluid pressure and phase changes of the fluid within the reservoir and production rates, may be simulated for various downhole pressure scenarios. Simulations may include cases where additional wellbore are drilled and/or fluid injection schedules are implemented. These predictions help inform the future operation of the reservoir.

The grid of points or cells used to numerically represent the reservoir may be relatively coarse over much of the reservoir because the spatial variation of pore fluid pressure is gentle. The coarseness makes the computational cost of the simulation tractable. However, near production wellbores, particularly near perforations in the wellbore casing or in the neighborhood of hydraulic fractures, pore fluid pressures may vary rapidly spatially making pressure gradients steep. In addition, such steep pressure gradients may induce phase changes in the reservoir fluid, for example “condensates”, i.e., oil precipitating from hydrocarbon gas, may form, or gas may come out of solution, i.e., out-gassing. Accurately simulating these steep gradients require densely sampled grids at least in the region surrounding the wellbores. However, having a densely sampled grid throughout the reservoir model may make performing reservoir simulations computationally unfeasible.

To overcome the problem of requiring dense sampling in some regions but not requiring it, or being able to afford it everywhere, local grid refinement (LGR) may be used to produce a plurality of densely sampled local grids which may be coupled to the reservoir-wide coarse grid. However, in reservoirs containing hundreds or thousands of wells with complex curved and/or branching trajectories defining densely sampled local grids manually may be intractable due to the man-hours required. The disclosed invention describes methods and systems for defining a plurality of densely sampled local grids automatically with minimal human interaction thus overcoming the computational and human-labor constraints that previously prevented accurate reservoir simulations for realistic large scale hydrocarbon reservoirs.

FIG. 1. depicts a hydrocarbon reservoir in accordance with one or more embodiments. As illustrated in FIG. 1, a subterranean region (100) may include one or more hydrocarbon reservoirs (106) with various production wells (102). Likewise, a hydrocarbon reservoir region may also include one or more injection wells (104) that include functionality for enhancing production by one or more neighboring production wells. For example, injection wells (104) may inject fluid to maintain reservoir pressure and to sweep hydrocarbons, such as oil and gas, through the hydrocarbon reservoir towards the production wells. As shown in FIG. 1, wells may extend from the surface of the Earth through various overburden layers to penetrate the hydrocarbon reservoir that may be bounded by an upper reservoir surface (106a) and a lower reservoir surface (106b).

In accordance with one or more embodiments, a reservoir model may be created or obtained for the hydrocarbon reservoir. Typically, the reservoir model may represent of the spatial variation of reservoir properties. For example, the reservoir properties may include the geometry of the reservoir, including the location of the geological boundaries that define the upper and lower surfaces of the reservoir and the location of any geological faults, fracture and fracture swarms within the reservoir. The reservoir properties may also include physical properties such as, without limitation, electrical resistivity, self-potential, acoustic wave propagation velocity, density, gamma-ray emission and the pressure of the reservoir fluid and the temperature of the reservoir. The reservoir properties may also include information derived, inverted, or interpreted from these physical properties, such as rock or “facies” types, e.g., carbonate, sandstone, shale, salt. Further, reservoir properties may include characteristic of particular importance to the study of reservoir fluid percolation through the reservoir. Specifically, reservoir properties may include porosity, quantifying the amount of volume between the grains of a rock per unit volume of bulk rock, that may be occupied by reservoir fluid; permeability quantifying the ease with which reservoir fluids may percolate through the rock; the initial pressures of the reservoir fluid and the temperature of the reservoir. Further, the reservoir properties may include the composition of the reservoir fluids, and their phases, i.e., liquid or gas. The reservoir model may also include the trajectories, completion data and production histories for a plurality of existing wells, and the proposed trajectories of potential future wells.

Such a reservoir model may be produced using deep sensing measurements, such as seismic surveys, gravity surveys, and electromagnetic surveys. In addition, the reservoir model may include information from well logs, acquired using wireline, coiled tubing, and drill pipe conveyed tools and acquired during or after the drilling of wells. In addition, the reservoir model may include information from core samples acquired as whole-core or as side-wall cores.

A reservoir modeling system may be used to generate the reservoir model, including receiving the measurement and data described in the preceding paragraphs, integrating, interpreting and displaying the data in a manner in which the reservoir model may be interrogated by operators of the hydrocarbon reservoir. Such a reservoir model may be created once, or more likely may be created and/or modified many times over the productive life of the hydrocarbon reservoir as additional information about reservoir properties are acquired and as the history of reservoir fluid production is extended.

FIG. 1 also shows a well planning system (110) that may be used to contemplate planned wells (108) (e.g., planned wellbore path (112)) to penetrate the hydrocarbon reservoir (106) at a location (113). Wellbores may be drilled along a trajectory guided by the planned wellbore path (112) using a drilling system (114). Although FIG. 1 shows, for clarity, only a handful of vertical wells, this simplification is not intended to limit the scope of the invention in anyway. Realistic hydrocarbon reservoirs may contain hundreds, or thousands, of wells each of which may be vertical, highly-deviated, or horizontal and which may contain multiple branches (“multilaterals”) from a single parent wellbore.

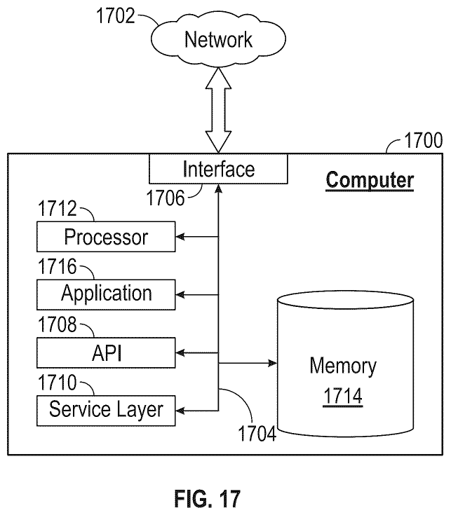

Both the reservoir modeler and the well planning system may use a computer system, such as the computer system (1700), depicted in FIG. 17, and equipped with dedicated software configured to form, manipulate and display the reservoir model, or plan and display the well plan, including the well trajectory, respectively.

FIG. 1 further depicts a reservoir simulation model (116) that may digitally represent all or a portion of the hydrocarbon reservoir in a reservoir simulator (120). The reservoir simulation model (116) may be composed of a plurality of cells, such as cells (118), The reservoir simulator (120) may be used to simulate, or model, the percolation of reservoir fluid through the hydrocarbon reservoir.

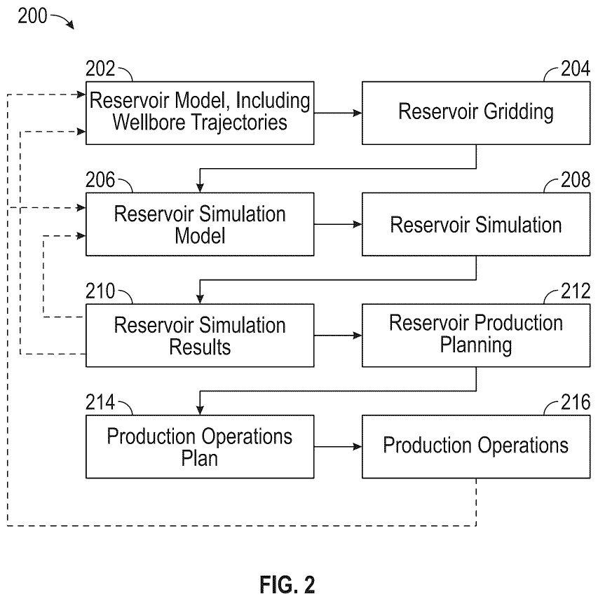

FIG. 2 shows a flowchart (200) in accordance with one or more embodiments. The flowchart (200) indicates the entities that may be generated from a reservoir model (202) and the processes used to generate them. Specifically, a reservoir simulation model (206) may be generated from the reservoir model (202). Typically, the generation of the reservoir simulation model (206) requires the gridding of the reservoir model (202) using a reservoir gridding process (204). A primitive reservoir gridding process (204) may generate a simple uniform grid, such as a cartesian grid with spatially invariant cell size, to represent the entire reservoir. However, obtaining accurate results of subsequent reservoir simulation may require portions of the reservoir to be described by finer grids, with smaller cell sizes. In particular, portions of the reservoir surrounding wellbores may require finer grids and such grids may be cylindrical grids rather than cartesian grids.

The reservoir simulation model (206) may be used by a reservoir simulator to perform reservoir simulation (208). The reservoir simulator may include computer system, such as the computer system (1700), and software with functionality for simulating percolation or the flow of reservoir fluid through the reservoir in response to natural or anthropogenic pressure gradients.

For example, the reservoir simulator may solve a set of mathematical governing equations that represent the physical laws that govern fluid flow in porous, permeable media. For example, the flow of a single-phase slightly compressible oil with a constant viscosity and compressibility is captured by Darcy's law, the continuity condition and the equation of state and may be written as:

$${∇}^{2} p ( x , t ) = \frac{φμ {c}_{t}}{k} \frac{\partial p ( x , t )}{\partial t} \qquad Equation ( 1 )$$

where p represents fluid in the reservoir, x is a vector representing spatial position and t represents time. φ, μ, cₜ, and k represent the physical and petrophysical properties of porosity, fluid viscosity, total combined rock and fluid compressibility, and permeability, respectively. ∇² represents the spatial Laplacian operator.

Additional, and more complicated equations, such as the Peng-Robinson EoS, may be required when more than one fluid, or more than one phase, e.g., liquid and gas, are present in the reservoir. For example, the formation of “condensates”, i.e., oil condensing from a vapor state, gas, or outgassing of natural gas previously dissolved within a hydrocarbon liquid may be simulated.

Further, when the physical and petrophysical properties of the rocks and fluids vary as a function of position the governing equations may not be solved analytically and must instead be discretized into a grid of cells or blocks. The governing equations may then be solved by one of a variety of numerical methods well known to one of ordinary skill in the art, such as, without limitation, explicit or implicit finite-difference methods, explicit or implicit finite element methods, or discrete Galerkin methods.

The reservoir simulation results (210) may include the simulation of production rates, volumes and compositions from existing hydrocarbon wells over the history of production from the hydrocarbon reservoir. One of the purposes of simulating past production history is to validate the reservoir simulation model. The reservoir simulation results (210) may be compared to observed reservoir and individual well production history. When the simulated and observed historical production match to within a satisfactory tolerance the reservoir simulation model may be considered to be validated, and future production histories may be predicted with some confidence. However, when simulated and observed historical production do not match to within a satisfactory tolerance the reservoir simulation model (202) may be altered or updated to achieve a better match. In some embodiments, the reservoir model (202) may be updated, and the reservoir gridding (204) repeated, to obtain an updated reservoir simulation model (206). This process of comparing simulated and observed production history and updating the reservoir simulation model (206) may be termed “history matching”.

In addition to history matching, a validated reservoir simulation model may be used to predict future production as a result of various production operations scenarios. For example, production as a result of drilling one or more proposed new wellbore may be simulated. As another example, the production expected from commencing or accelerating the injection of water through a plurality of injection wells to maintain reservoir pressure and sweep the hydrocarbon fluid towards production wells may be simulated, in a process that may be termed reservoir production planning (212). The economic value of the predicted hydrocarbon production may be compared with the financial costs of the production operation (drilling the wells or injecting the fluid) to determine which if any of the production operation scenarios to include in a production operations plan (214). The resulting production operations plan (214) may be used to guide current and future production operations (216). In many cases, additional data, including hydrocarbon production data and reservoir property data acquired during current and future operations may be used to update the reservoir simulation model (206) and repeat the reservoir simulation over the productive life of the hydrocarbon reservoir.

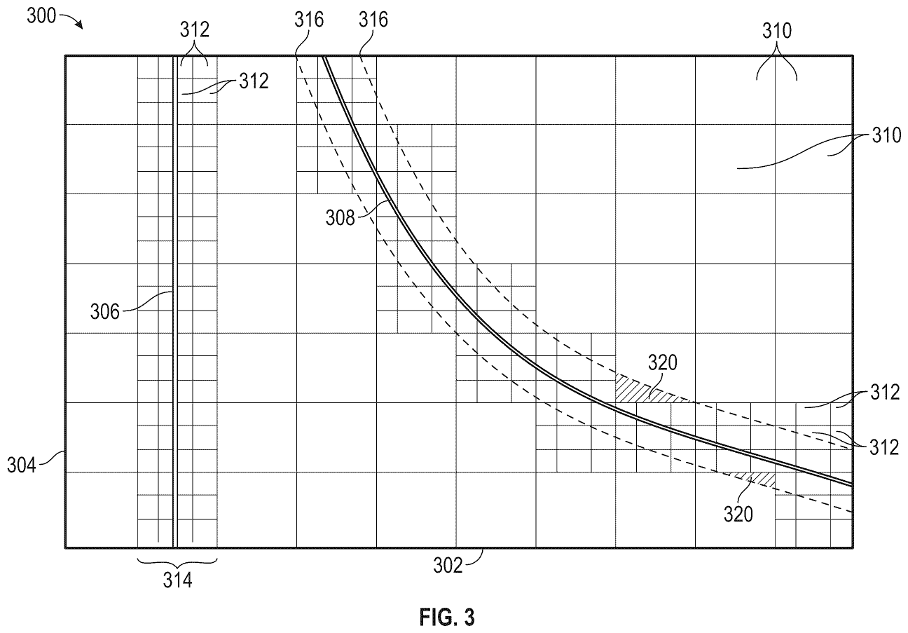

FIG. 3 depicts a reservoir simulation grid (300) in accordance with one or more embodiments. For visual simplicity, the reservoir simulation grid (300) is shown as a two-dimensional (“2D”) grid although in most case the reservoir simulation grid is three-dimensional (“3D”). The horizontal axis (302) of the grid represents horizontal distance, perhaps in a North-South direction, while the vertical axis (304) of the grid represents depth, for example depth below the surface of the earth or a datum, such as mean sea level. Two example wellbores are depicted on the reservoir simulation grid (300). The first wellbore (306) is a vertical wellbore, while the second wellbore (308) is a deviated wellbore.

Much of the reservoir simulation grid (300) is composed of a relatively coarse cells, such as cells (310), that provides adequate accuracy for reservoir simulation in regions that are far from the nearest wellbore, e.g., wellbore (308) and represent regions where the spatial variation of reservoir properties is relatively slowly changing and/or of small amplitude. Although the cells (310) are indicated to be approximately equidimensional, i.e., square in 2D or cubic in 3D, in practice cells have much smaller vertical extent than horizontal extent reflecting the more rapid vertical than horizontal variation of the subsurface that is typical in most locations. However, in regions closer to wellbores, or where the spatial variation of reservoir properties changes rapidly and significantly in magnitude, a finer grid may be required to provide adequate accuracy for reservoir simulation. These regions of finer grid may require smaller cell sizes, such as the cells (312).

Frequently, reservoirs may contain several hundred to several thousand wellbores and defining and creating the corresponding grids in the reservoir simulation model is too time consuming to be practical. Although, forming refined grids around vertical, or near vertical, wellbores, such as wellbore (306), or more precisely around wells that are parallel to one of the axes of the course grid, may be automated with relative ease by dividing one or a handful of columns of cells in the coarse grid to form a local refined grid (314), forming a locally refined grid for a more common highly deviated wellbore, such as wellbore (308) is much more complex and time-consuming to perform manually. Locally refined grids created manually for wellbores such as wellbore (308) may extend beyond the region required for accurate reservoir simulation (indicated by the dashed lines (316) in FIG. 3) in some places, but fail to enclose the required areas, such as areas (320) in other places.

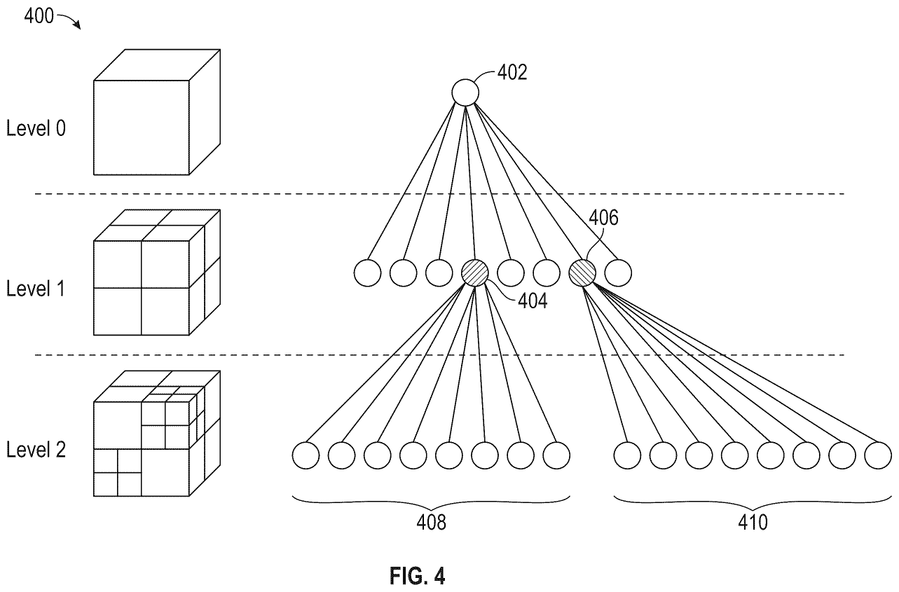

In accordance with one or more embodiments, octree (in 3D) or quadtree (in 2D) data structures may be used to automatically define locally refined grids. Note, a quadtree may sometimes be the appropriate choice when a reservoir simulation model represents a thin reservoir that exhibits a high degree of vertical homogeneity. An octree, such as the octree (400) displayed in FIG. 4, is a tree data structure in which each internal node has either zero or exactly eight children. Octrees are most often used to partition a three-dimensional space by recursively subdividing it into eight octants. Quadtrees are the 2D analog of octrees with each internal node has exactly four children.

Each node in an octree, such as nodes (402, 404 and 406) may further subdivide the space it represents into eight children or octants, such as nodes (408, 410). In a point region octree, each node stores an explicit three-dimensional point, which is the “center” of the subdivision for that node; the point defines one of the corners for each of the eight children. In a matrix-based octree, the subdivision point is implicitly the center of the space the node represents. The root node of a point region octree may represent infinite space; the root node of a matrix-based octree must represent a finite bounded space so that the implicit centers are well-defined.

An octree, such as octree 400 may be thought of as consisting of levels or depths. Although “depth” is frequently used in the literature describing octrees, herein the term “level” is used instead to clearly distinguish the level within the octree from the depth below a datum, such as mean sea level, that is frequently used by reservoir simulators. In some embodiments, when gridding a reservoir simulation model, the root node (402) positioned in level zero may encompass the entire reservoir simulation grid, that itself may digitally represent the entire reservoir. In other embodiments, an octree may be defined with a root node at level zero for each cell of the original coarse grid.

Since embodiments may accept an arbitrary set of cells within the original coarse grid as the target region for refinement, octrees can be used to automatically refine around different types of target geometries such as a set of points (e.g., well perforations), line segments (e.g., wells), or manifolds (e.g., fault planes) in 3D space. Each of these types of targets, and other requiring local grid refinement, may be represented in the reservoir model. Each node may be identified as representing a cell or a Cartesian box of cells that requires refinement or further refinement

Proposed embodiments also readily support spatially varying refinement factors, dynamic refinement regions that change over time, and the dilation of the refinement region to include additional layers of cells outside the boundary of the target region. For example, in a first region immediately adjacent to well perforations a high degree of spatial refinement, i.e., very small grid cells, may be required, while further from the well perforations, in a second region forming a shell around the first region a lower degree of spatial refinement may be adequate.

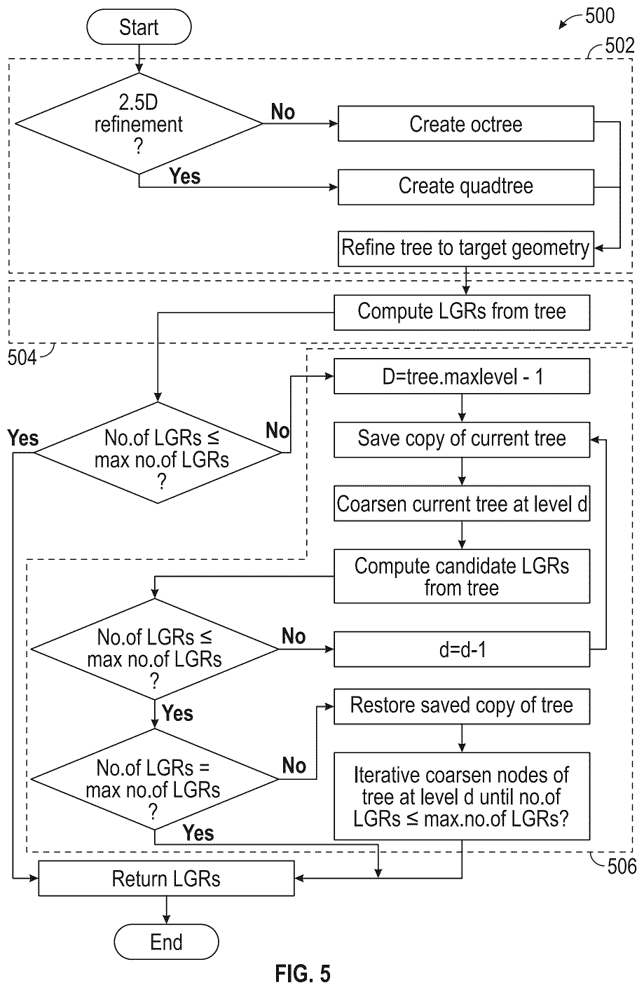

A workflow (500), in accordance with one or more embodiments, to address the challenge of automatically defining an appropriate plurality of locally refined grids to balance the needs of accuracy and computational cost is depicted in FIG. 5. The workflow consists of three primary steps: the creation of the tree data structure (502) for a given target geometry; the generation of local grid refinements (“LGR”) definitions from the tree (504); and the optimization of the tree data structure to reduce the number of LGRs generated (506).

The creation of the tree data structure (502) for a given target geometry includes a space-partitioning tree data structure as the scaffolding of the LGR generation process. For example, if the required local grid refinement is two-dimensional or 2.5-dimensional (i.e., extends through all the layers of the original coarse grid), then a quadtree data structure is used, otherwise an octree is used to generate three-dimensional LGRs. Each node of the tree data structure contains (i, j, k)ₘᵢₙ and (i, j, k)ₘₐₓ variables to represent a box sub-region of the original coarse grid. The tree starts with a single node at level=0, representing the entire original grid with dimensions nₓ×n_{y}×n_{z}. The children of a quadtree node at level=1 represent each quadrant of the original grid with dimensions

$$\frac{{n}_{x}}{2} \times \frac{{n}_{y}}{2} \times {n}_{Z} ,$$

while children of a octree node at level=1 represent each octant of the original grid with dimensions

$$\frac{{n}_{x}}{2} \times \frac{{n}_{y}}{2} \times \frac{{n}_{z}}{2} .$$

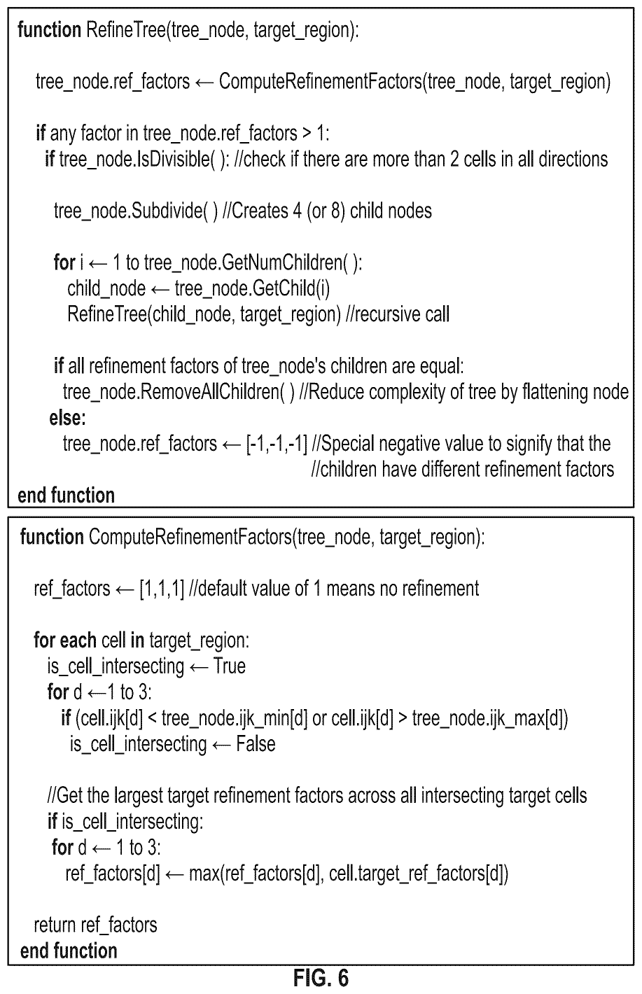

Starting from the top node at level=0, the leaf nodes of the tree are recursively refined as long as the box region represented by the leaf node intersects the target region identified as requiring refinement and the box covers two or more grid cells in all three directions. Examples of functions that may be used are presented as computer-executable code in FIG. 6. The function ComputeRefinementFactors computes the refinement factors for a tree node by first determining the cells in the target refinement region that intersect with the box region of the tree node, and then computing the largest target refinement factors across those intersecting cells. LGRs with spatially varying refinement factors can be generated by assigning different target refinement factors to the cells in the target region. It is worth noting that for grids whose dimensions are not exactly a power of 2, the resulting quadrants (or octants) at a given level of the tree may not be of equal size.

In accordance with one or more embodiments, the LGRs may be generated from the tree. The generation may extract spatial location information from all the tree nodes with refinement and reducing them to a minimal set of LGR “boxes”, where each box is defined by the (i, j, k)ₘᵢₙ and (i, j, k)ₘₐₓ, and (x, y, z) refinement factor integer triplets. This set of LGR box definitions can then be fed directly into any reservoir simulator that supports Cartesian LGRs.

The first step in this process is a recursive function that appends an LGR box object to a list each time it encounters a tree node where at least one of the refinement factors is greater than unity. If the refinement factors of the tree node are positive integers, it implies that either the tree node has no children, or all its children have the same refinement factors, which means that no further recursion is required. In contrast, if any tree node has [−1, −1, −1] as its refinement factors (as set in the RefineTree function of FIG. 6, then the children of that node have different refinement factors, and the function must recurse deeper to gather LGR boxes from the child nodes. During this recursion, it is prudent to check for opportunities to merge LGR boxes gathered from the child nodes to reduce the overall number of LGR boxes appended to the list.

For example, if the refinement factors of the north-west (NW) and north-east (NE) child nodes of a quadtree node are equal and are different from the refinement factors of the south-west and south-east child nodes, then the 2 LGR boxes from the NW and NE children can be merged to form a single “rectangular” LGR box. This results in a total of 3 LGR boxes from the children instead of 4 boxes. Additional such merge checks can potentially reduce the number of LGR boxes produced by a quadtree node to 2 boxes or even 1 box. The extension of these merge checks to octree nodes is more involved because there are significantly more permutations to check between the 8 child nodes. However, an easy-to-implement alternative that tends to work well in practice is to perform quadtree-like merge checks for the 4 upper child nodes and the 4 lower child nodes separately.

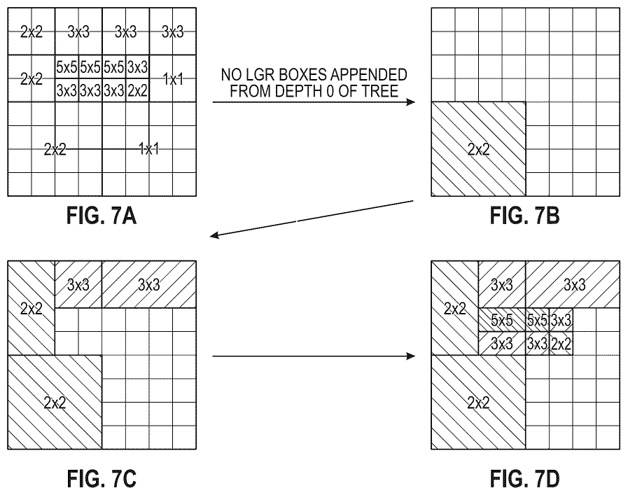

FIGS. 7A-7D illustrates how this recursive function produces a list of LGR boxes from a refined quadtree. FIG. 7A shows the quadtree leaf nodes with target refinement factors. FIG. 7B highlights one LGR box appended from level 1 of the tree. FIG. 7C depicts 3 LGR boxes appended from level 2 of the tree, and FIG. 7D shows 6 LGR boxes appended from level 3 of the tree.

Although this method reduces the number of LGR boxes by checking for opportunities to merge nodes that share a common parent node, it does not attempt merges between nodes that share a grandparent node or any earlier ancestor. This is evident from the example in FIG. 7D, where 3 pairs of boxes with 5×5 refinement and 3×3 refinement have not been merged further. Therefore, an additional global merge step is performed to further reduce the number of LGR boxes. This global merge is based on a rectangle decomposition workflow originally proposed for computing moments on binary images (I. M. Spiliotis and B. G. Mertzios, “Real-time computation of two-dimensional moments on binary images using image block representation,” in IEEE Transactions on Image Processing, vol. 7, no. 11, pp. 1609-1615 November 1998), where the boxes are first split into slices of unit width in a particular direction and then the split pieces are reconnected along an orthogonal direction. For 2.5D LGR boxes obtained from a quadtree, this global merge operation is repeated for the two splitting directions, x and y, and the result with the least number of LGR boxes is selected.

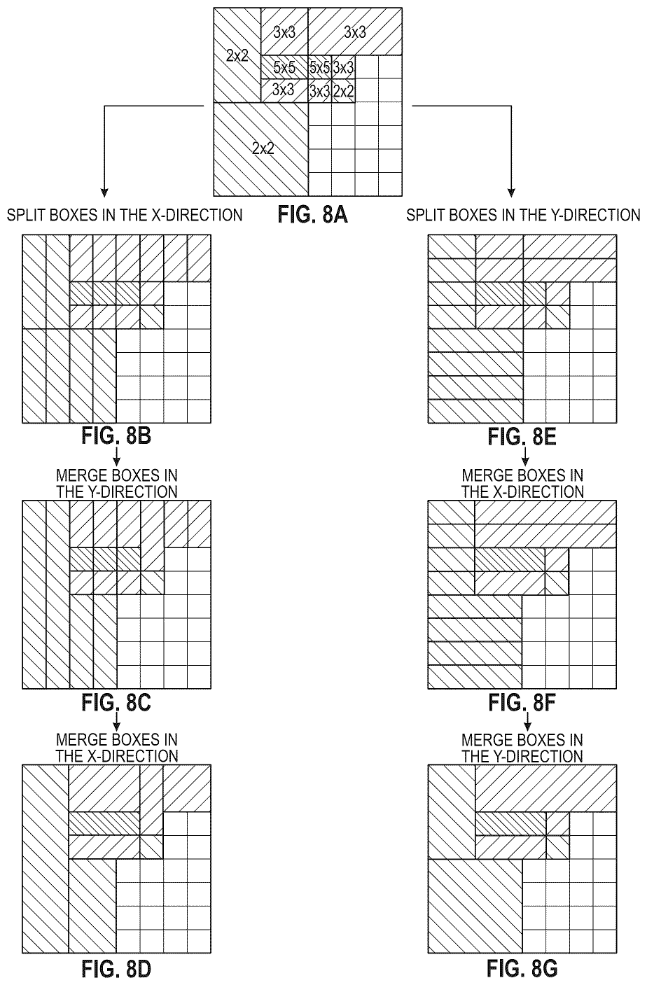

FIGS. 8A-8G illustrate this global split-and-merge algorithm for the 10 LGR boxes in FIG. 7D. The extension of this global merge algorithm to 3D LGR boxes involves an additional recursive split-and-merge operation, since after splitting the 3D boxes in the primary splitting direction, each “slice” may contain different pieces of boxes representing a 2D problem of its own. The box pieces in each slice are then split again in a secondary splitting direction that is orthogonal to the primary splitting direction, and the resulting pieces are merged along the remaining direction. For example, the 3D boxes can be first split in the x-direction, and the pieces in each yz-slice can be further split in the y-direction and then merged along the z-direction. In this work, the 3D split-and-merge operation is repeated for the 6 different combinations of primary and secondary splitting directions, and the result with the least number of LGR boxes is selected.

For example, FIG. 8A depicts 10 LGR boxes gathered from a quadtree. Splitting the boxes in the x-direction yields FIG. 8B containing 20 LGR boxes. Then merging the 20 LGR boxes of FIG. 8B in the y-direction yields FIG. 8C with 17 LGF boxes, and finally merging the boxes of FIG. 8C in the x-direction produces 8 LGR boxes. Alternately, splitting the LGR boxes in FIG. 8A in the y-direction gives FIG. 8E containing 18 LGR boxes. Merging these 18 LGR boxes in the x-direction yields FIG. 8F containing 14 boxes, and finally merging the boxes depicted in FIG. 8F in the y-direction yields 7 LGR boxes.

Returning to FIG. 5, in step (506) of FIG. 5 the tree may be optimized, in accordance with one or more embodiments. The objective of optimizing the tree is to simplify the data structure in a way that systematically and reliably reduces the number of LGR boxes that are generated, while also minimizing the computational cost (e.g., number of refined grid cells) incurred by those LGRs. While the LGR box merging processes discussed in the previous section attempt to reduce the number of LGRs while keeping the total refinement region fixed, this tree optimization step attempts to further reduce the number of LGRs by allowing expansion of the region of refinement.

The core idea in this step is that if a particular node in the tree has heterogeneous child nodes (i.e., the children have different refinement factors), then it is possible to potentially reduce the total number of LGRs generated by the tree by flattening that parent node. Flattening a node involves assigning the largest refinement factors of its children to itself, and then deleting its children. Although the flattening of a node may not always reduce the total number of LGRs generated, it is easy to see that in the limit where all nodes of the tree are recursively flattened from bottom to top, leaving only the topmost node, the tree would then only produce a single LGR that encompasses the entire grid. In practice, the node flattening operations are terminated once the number of LGRs generated by the tree decreases below some user-defined threshold.

As shown in FIG. 5, the tree is optimized in two levels of granularity. First, it is optimized level-by-level, and once the appropriate level is found, it is optimized node-by-node within that level. In the first stage, all eligible nodes at a given level of the tree are flattened and LGR boxes are generated from the modified tree. A node is considered eligible for flattening if it has children and causes the total generated LGR count to decrease when the flattening is applied. Most tree nodes, especially ones at higher levels of the tree, have zero impact on the number of LGRs generated when flattened. Hence, it is computationally more efficient to filter out such nodes upfront, and only consider nodes that will reduce the total LGR count. However, evaluating the change in the overall LGR count caused by a particular node flattening operation (ΔN_{LGR}) is also computationally expensive, since it involves generating LGR boxes from the whole tree using the local and global box merging algorithms discussed in the previous section. Consequently, in embodiments disclosed herein this excessive cost is avoided by using an estimate of the change in the overall LGR count ( [symbol] ≈ΔN_{LGR}) that is cheaper to compute. This estimate is calculated as the difference between the number of LGR boxes generated by the chosen node and all its children, and the number of LGR boxes generated by that node after flattening (which is always equal to 1). This process is significantly less computationally expensive than executing the box merge algorithms on the entire tree since this calculation only calls the LGR box merge algorithms on an isolated fraction of the tree (i.e., only the node to be flattened and its descendants). All tree nodes that produce a negative [symbol] value are considered eligible for flattening.

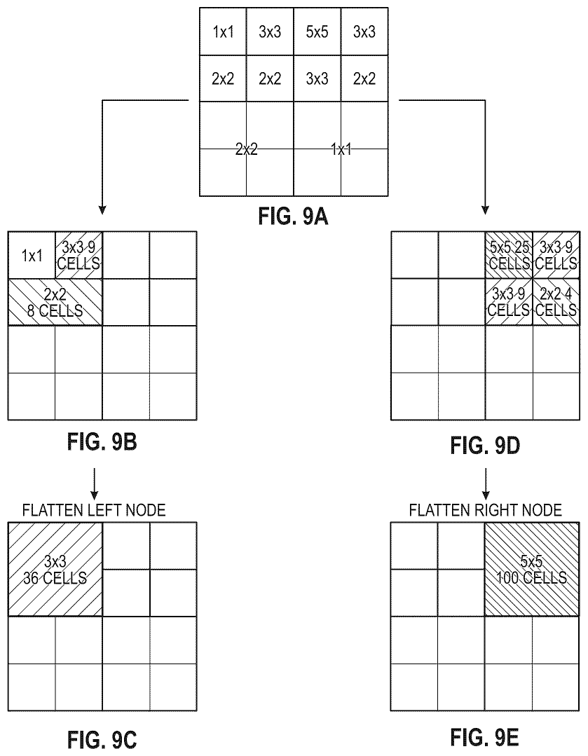

The flattening process starts at the penultimate depth of the tree and continues up level-by-level until the generated LGR count falls below a user-defined threshold or maximum number. Once the terminating level is found, the tree is restored to a state just before that terminating level was flattened. Since it is highly likely that only a fraction of the eligible tree nodes in the terminating level needs to be flattened to satisfy the user's maximum LGR count threshold, the order in which those nodes are selected is important. A node flattening operation typically increases the overall computational cost (i.e., number of active cells) of a simulation by either expanding the refinement region, increasing the refinement factors applied to a given region, or both. Therefore, it is advantageous to prioritize the flattening operations that incur the least additional computational cost. In some embodiments, each node flattening operation may be assigned a cost representing the increase in the number of active grid cells caused by that operation. In the second stage of the optimization, the eligible tree nodes of the terminating level are sorted in ascending cost order, and a bisection search is utilized to find the cutoff point for the set of node-flattening operations that maximizes the number of LGRs generated from the tree, without exceeding the user-specified maximum. FIG. 9A-9E4 presents a visual example of how the cost and estimated change in LGR count is calculated for two different node flattening operations in a quadtree of a 4×4 grid.

FIG. 9A depicts the leaf nodes of a quadtree with their target refinement factors. The first possible node flattening processes are depicted in FIGS. 9B and 9C, while the second possible node flattening processes are depicted in FIGS. 9D and 9E. In FIG. 9B, the upper left quadrant shows two LGRs (and one unrefined cell) containing a total of 17 refined cells. Flattening this quadrant as described above, and shown in FIG. 9C, produces one LGR with 36 refined cells, resulting in an increase of 19 in the number of refined cells. In contrast, in FIG. 9D the upper right quadrant contributes four LGRs containing 47 refined cells. Flattening this quadrant as described above, and shown in FIG. 9E, produces 100 refined cells, resulting in an increase of 53 in the number of refined cells

The LGR disclosed above may be considered to be a static LGR. A static LGR is performed prior to the commencement of reservoir simulation and the resulting grid thereafter remains unchanged. However, other embodiments may include dynamic LGRs where the LGR configuration changes in response to features of the reservoir simulation, such as the spatial evolution of a simulated injected fluid front.

In contrast to static LGRs which are fixed over the duration of the simulation, dynamic LGRs can be added or removed at different time points depending on the need for additional grid resolution. Dynamic LGRs may be more computationally efficient than static LGRs in applications that involve tracking dynamic solution features, such as refining around an evolving fluid saturation front, because the local refinements can be deactivated or removed after the feature of interest has passed. To generate dynamic LGR definitions for a target refinement region that changes over time, each tree node may be augmented to also store a sorted list of disjoint time intervals during which it is active. Each time interval may consist of a start time at which the refinement is added or re-activated, and an end time at which the refinement is temporarily deactivated or completely removed from the grid. The active time interval list of a tree node may be computed by merging the active time intervals of all the target cells intersecting that node.

A standard process using a stack data structure may be used to efficiently merge two sorted lists of disjoint time intervals in linear time. The definition of an LGR box may also be extended to contain a list of active time intervals, and the LGR box merging operations are updated so that if box A and box B can be merged spatially to form box C, then the list of active time intervals of box C is the union of the time intervals of boxes A and B. Finally, in the tree optimization step, the computational cost variable used to sort node flattening operations may be modified to account for the active/inactive time intervals of the node being flattened. For example, the space-time computational cost of a node flattening operation can be computed as the product of the number of active grid cells created by the flattening operation and the total time duration over which the tree node is active.

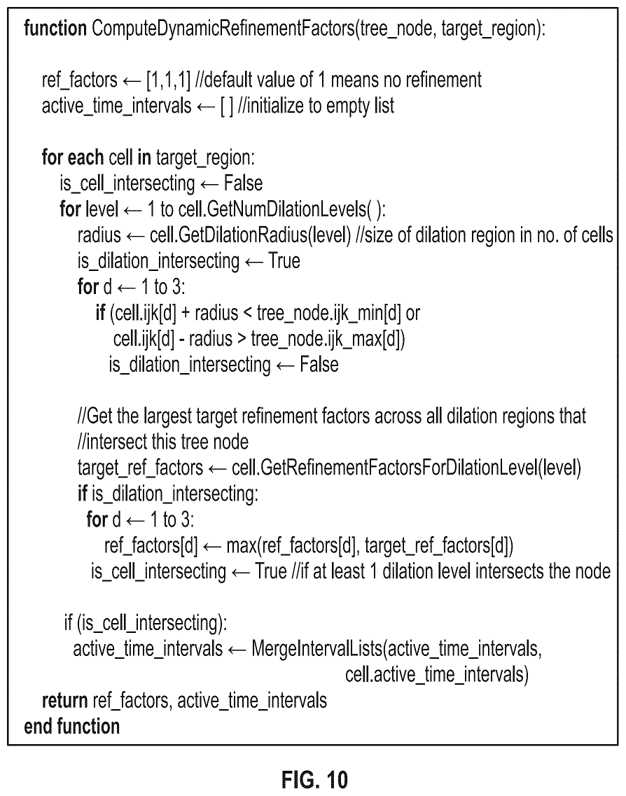

In still other embodiments, the region targeted for refinement may be extended or dilated. By modifying the function that checks for intersections between a tree node and a particular cell inside the target region, it is possible to “dilate” the target refinement region to also include cells that are within a user-specified distance from the boundary of the original target region. By combining spatially varying refinement factors and different refinement region dilation sizes, a graded refinement pattern may be produced where the refinement factors of LGRs change based on their distance to the original refinement target. The function “ComputeDynamicRefinementFactors” given in FIG. 10 shows how the ComputeRefinementFactors function in FIG. 6 can be updated to support both the dynamic LGR and refinement region dilation extensions discussed above.

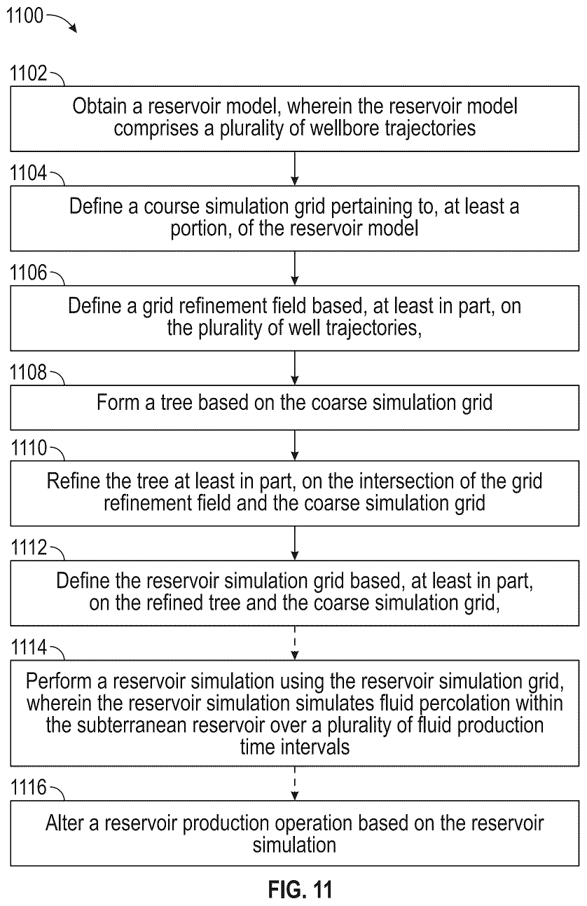

FIG. 11 shows a flowchart (1100) in accordance with one or more embodiments. In Step 1102 a reservoir model may be obtained. The reservoir model may include a plurality of wellbore trajectories in addition to a representation of the spatial distribution of reservoir properties.

In Step 1104 a coarse simulation grid pertaining to, at least a portion, of the reservoir model may be defined.

In Step 1106 a grid refinement field may be determined based, at least in part, on the plurality of well trajectories. The grid refinement field may be determined based, at least in part, on the spatial location of points in the field relative to perforation positions along the plurality of wellbore trajectories.

In Step 1108 a tree may be formed based on the coarse simulation grid and in Step 1110 the tree may be refined based, at least in part, on the intersection of the grid refinement field and the coarse simulation grid. Refining the tree may include growing the number of leaves on the tree based, at least in part, on the grid refinement field, where each leaf on the grown tree comprises a grid refinement factor determined by the grid refinement field; and pruning the leaves on the grown tree based on the grid refinement factor of adjacent leaves. The grid refinement field may be updated based, at least in part, on the geometry of the grown tree.

In Step 1112 the reservoir simulation grid may be defined based, at least in part, on the refined tree and the coarse simulation grid.

In Step 1114 a reservoir simulation may be performed using the reservoir simulation grid, wherein the reservoir simulation simulates fluid percolation within the subterranean reservoir over a plurality of fluid production time intervals.

In Step 1116 a reservoir production operation may be altered based on the reservoir simulation. For example, the reservoir production operation may be selected from the group consisting of drilling, using a drilling system, a wellbore; changing, using a choke, the production rate of at least one well, and changing, using a pumping system, the injection rate of a stimulation fluid into at least one well.

Using the reservoir simulation system, the grid refinement field may be updated based, at least in part, on a result of the reservoir simulation, the tree may be refined based, at least in part, on the intersection of the updated grid refinement field and the coarse simulation grid, the reservoir simulation grid may be updated based, at least in part, on the refined tree and the coarse simulation grid, and an updated reservoir simulation may be performed using the updated reservoir simulation grid, wherein the updated reservoir simulation simulates fluid percolation within the subterranean reservoir over a fluid production time interval later than the fluid production time intervals in the plurality of fluid production time intervals.

Using the reservoir simulation system, the grid refinement field may be corrected based, at least in part, on a difference between a fluid production rate predicted by the reservoir simulation and an observed fluid production rate, the tree may be corrected based, at least in part, on the intersection of the corrected grid refinement field and the coarse simulation grid, the reservoir simulation grid may be corrected based, at least in part, on the corrected tree and the coarse simulation grid, and a repeated reservoir simulation may be performed using the corrected reservoir simulation grid, wherein the repeated reservoir simulation simulates fluid percolation within the subterranean reservoir over a fluid production time interval selected from the plurality of fluid production time intervals.

In this section, we present results demonstrating the proposed method on a two-phase reservoir flow problem, where the original unrefined grid has dimensions of 166×205×153 containing 5.2 million active grid cells. The LGR generation algorithm is used to generate local grid refinements around 114 wells in this model. These wells consist of over 5400 perforated grid cells distributed across different regions and depths of the grid, which are used as “point” targets defining the refinement region. Both 2.5D and 3D LGRs were generated for different levels of grid complexity and target refinement region dilation sizes.

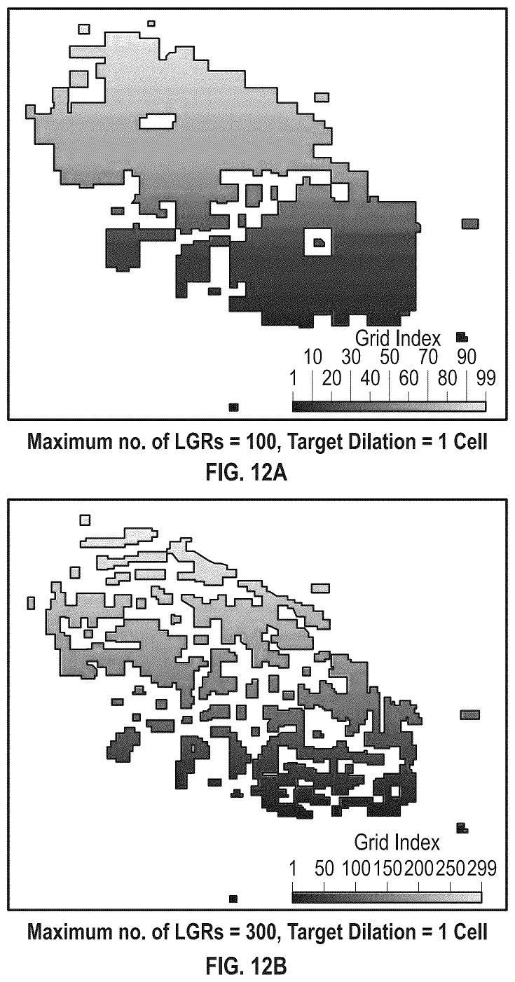

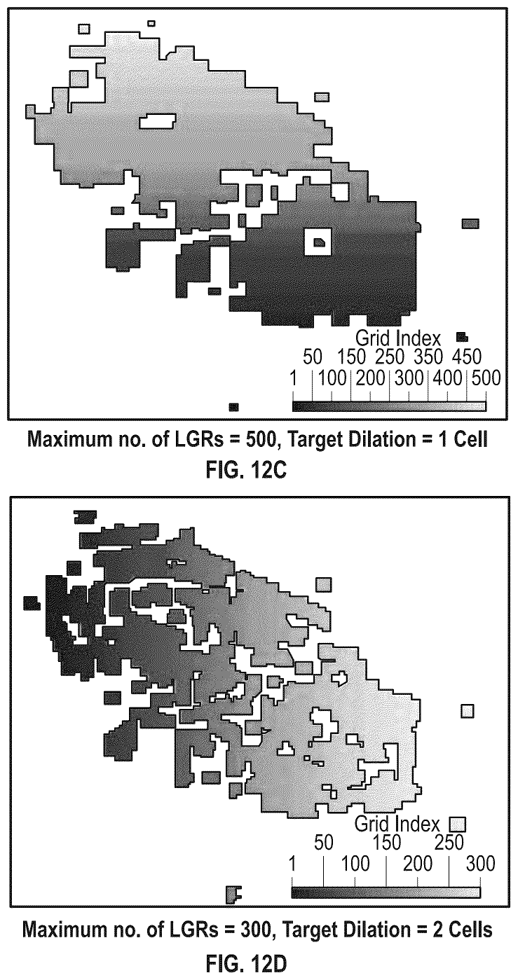

FIGS. 12A-12D illustrates different LGR configurations generated by the disclosed process for this problem at different levels of grid complexity controlled by the maximum number of LGRs. A constant refinement factor of 3×3 was used for all LGRs. FIGS. 12A-12C clearly demonstrate how the disclosed process covers the target refinement region with more precision and granularity as the maximum number of LGRs is increased. FIG. 12A corresponds to a maximum number of LGRs of 100, FIG. 12B corresponds to a maximum number of LGRs of 300, and FIG. 12C corresponds to a maximum number of LGRs of 500. FIG. 12D shows the effect of expanding the target region while keeping the maximum number of LGRs the same as in FIG. 12B. The LGR configuration in FIG. 12D appears “blockier” when compared to FIG. 12B since each LGR needs to cover a greater area.

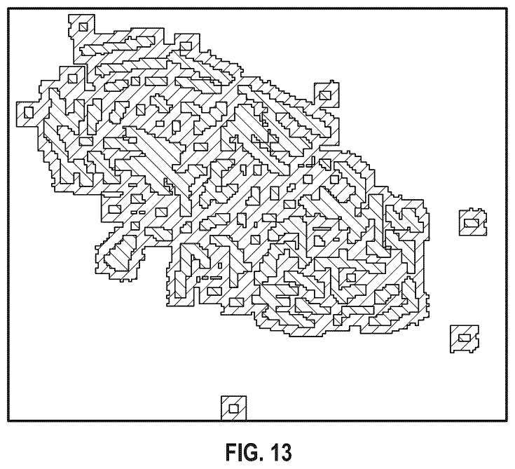

FIG. 13 shows a configuration of 1000 LGRs generated by the disclosed workflow in a level-set pattern, where larger refinement factors are applied to cells located closer to the original target (i.e., the well perforations). This configuration was generated by combining spatially varying refinement factors with multiple target dilation sizes.

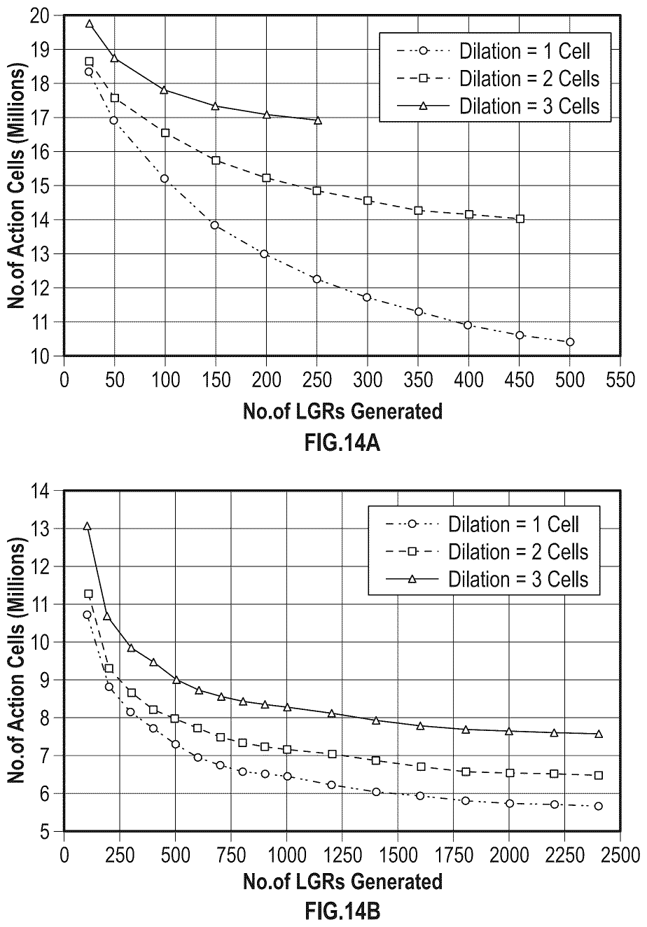

FIGS. 14A and 14B show how the number of active cells in the final refined grid change with the number of LGRs generated by the algorithm, for 2.5D and 3D LGRs respectively, with constant 3×3×1 refinement factors. Each plot contains three curves representing different levels of refinement region dilation. All curves exhibit a similar trend where the computational cost of the grid (represented by the number of active cells) decreases as the complexity of the grid (measured by the number of LGRs) increases. These results show that the proposed algorithm enables reservoir engineers to easily investigate the trade-off between grid complexity and computational cost by simply varying a single input parameter. It allows them to select an LGR configuration that does not significantly over-refine beyond the target refinement region but is also not too complex for I/O, visualization, or other postprocessing workflows.

Increasing the target region dilation size also has the expected effect of increasing the computational cost of the grid, since the local grid refinements need to cover a larger portion of the grid. It is worth noting that the grid configurations generated for 3D LGRs are significantly cheaper than those generated for 2.5D LGRs because the 3D LGRs can restrict the refinement region to a few cell layers above and below each target cell, instead of refining all the layers in the grid.

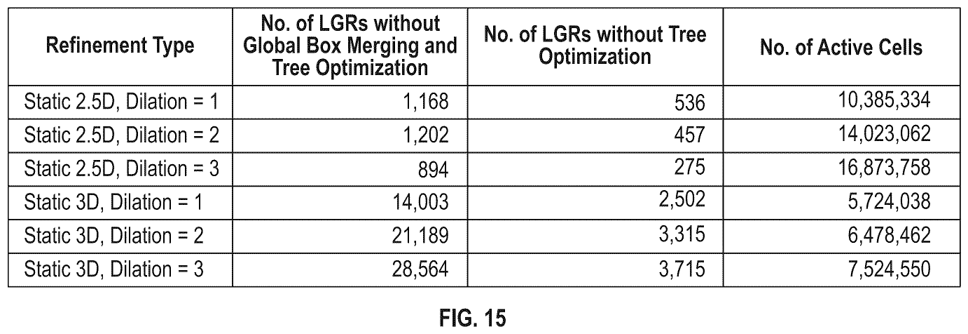

FIG. 15 shows the number of LGRs generated by the algorithm if some of its key steps, such as global box merging and tree optimization, are omitted. Comparing the numbers in the second and third columns shows that the global box merging step alone reduces the generated LGR count by a factor of 2-3× for the 2.5D refinement cases, and by a factor of 6-7× for the 3D refinement cases. The tree optimization step is required to achieve any further reductions in grid complexity, as shown in FIGS. 14A and 14B.

The reservoir simulation grid based on the refined grid obtained from the coarse grid using the refined tree may be used by a reservoir simulator to simulate the flow or percolation of fluids through the hydrocarbon reservoir under the influence of naturally occurring or anthropomorphic pressure changes. The result of the simulation may be either of equal accuracy to results obtained using conventional methods but obtained at dramatically reduced computational cost and elapsed time or may be of higher accuracy and obtained at essentially the same computational cost and elapsed time. In some cases, the results may be both of higher accuracy and reduced cost and elapsed time. Accordingly, the embodiments disclosed constitute a significant improvement over conventional methods intended for the same purpose.

The results of reservoir simulation may be used to predict the outcome of various operations common in the production of a hydrocarbon reservoir. Outcomes may include, without limitation, changes in production rates and changes in expected ultimately recoverable resources as well as the economic measures such as cash flow and return on investment. Operations common in the production of a hydrocarbon reservoir may include, without limitation, the choking of a production well flowrate, changes to the injection rate or a water flood, and various well stimulation operations such as hydraulic fracturing and acid stimulation. In particular, operations may include the planning, siting, and drilling of wells, such as production wells and water injection wells.

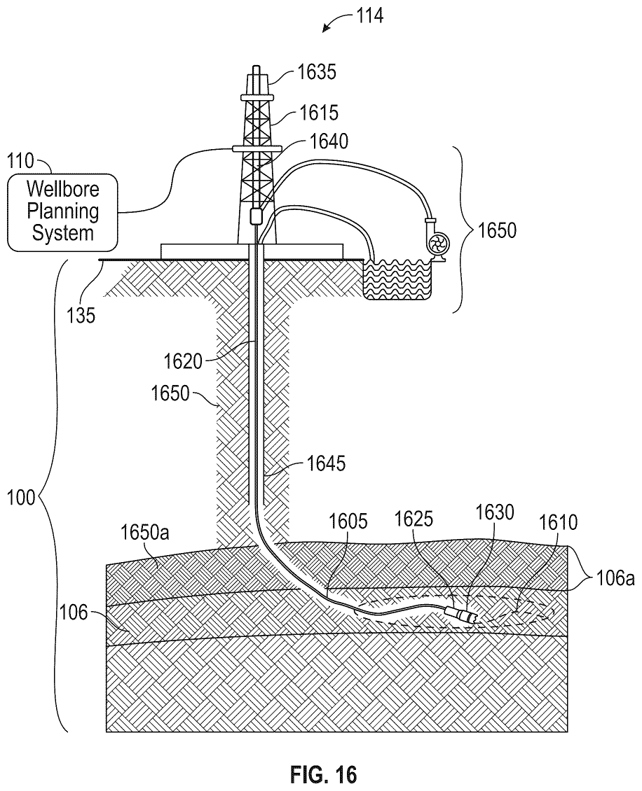

FIG. 16 illustrates a drilling system 114 in accordance with one or more embodiments. A wellbore 1605 may be drilled, using the drilling system 114, guided by the planned wellbore path 1610 to penetrate the hydrocarbon reservoir 106. Although the drilling system 114 shown in FIG. 16 is used to drill the wellbore 1605 on land, the drilling system 114 may also be a marine wellbore drilling system. The example of the drilling system 114 shown in FIG. 16 is not meant to limit the present disclosure.

As shown in FIG. 16, the wellbore 1605 may be drilled using a drill rig that may be situated on a land drill site, an offshore platform, such as a jack-up rig, a semi-submersible, or a drill ship. The drill rig may be equipped with a hoisting system, such as a derrick 1615, which can raise or lower the drillstring 1620 and other tools required to drill the wellbore 1605. The drillstring 1620 may include one or more drill pipes connected to form conduit and a bottom hole assembly 1625 (BHA) disposed at the distal end of the drillstring 1620. The BHA 1625 may include a drill bit 1630 to cut into rock 1650, including cap rock 1650a. The BHA 1625 may further include measurement tools, such as a measurement-while-drilling (MWD) tool and logging-while-drilling (LWD) tool. MWD tools may include sensors and hardware to measure downhole drilling parameters, such as the azimuth and inclination of the drill bit 1630, the weight-on-bit, and the torque. The LWD measurements may include sensors, such as resistivity, gamma ray, and neutron density sensors, to characterize the rock 1650 surrounding the wellbore 1605. Both MWD and LWD measurements may be transmitted to the surface of the earth 135 using any suitable telemetry system known in the art, such as a mud-pulse or by wired-drill pipe.

To start drilling, or “spudding in,” the wellbore 1605, the hoisting system lowers the drillstring 1620 suspended from the derrick 1615 towards the planned surface location of the wellbore 1605. An engine, such as a diesel engine, may be used to supply power to the top drive 1635 to rotate the drillstring 1620 via the drive shaft 1640. The weight of the drillstring 1620 combined with the rotational motion enables the drill bit 1630 to bore the wellbore 1605.

The near-surface of the subterranean region of interest 100 is typically made up of loose or soft sediment or rock 1650, so large diameter casing 1645 (e.g., “base pipe” or “conductor casing”) is often put in place while drilling to stabilize and isolate the wellbore 1605. At the top of the base pipe is the wellhead, which serves to provide pressure control through a series of spools, valves, or adapters (not shown). Once near-surface drilling has begun, water or drill fluid may be used to force the base pipe into place using a pumping system until the wellhead is situated just above the surface of the earth 135.

Drilling may continue without any casing 1645 once deeper or more compact rock 1650 is reached. While drilling, a drilling mud system 1650 may pump drilling mud from a mud tank on the surface of the earth 135 through the drill pipe. Drilling mud serves various purposes, including pressure equalization, removal of rock cuttings, and drill bit cooling and lubrication.

At planned depth intervals, drilling may be paused and the drillstring 1620 withdrawn from the wellbore 1605. Sections of casing 1645 may be connected and inserted and cemented into the wellbore 1605. Casing string may be cemented in place by pumping cement and mud, separated by a “cementing plug,” from the surface of the earth 135 through the drill pipe. The cementing plug and drilling mud force the cement through the drill pipe and into the annular space between the casing 1645 and the wall of the wellbore 1605. Once the cement cures, drilling may recommence. The drilling process is often performed in several stages. Therefore, the drilling and casing cycle may be repeated more than once, depending on the depth of the wellbore 1605 and the pressure on the walls of the wellbore 1605 from surrounding rock 1650.

Due to the high pressures experienced by deep wellbores 1605, a blowout preventer (BOP) may be installed at the wellhead to protect the rig and environment from unplanned oil or gas releases. As the wellbore 1605 becomes deeper, both successively smaller drill bits 1630 and casing 1645 may be used. Drilling deviated or horizontal wellbores 1605 may require specialized drill bits 1630 or drill assemblies.

The drilling system 114 may be disposed at and communicate with other systems in the wellbore environment. The drilling system 114 may control at least a portion of a drilling operation by providing controls to various components of the drilling operation. In one or more embodiments, the system may receive data from one or more sensors arranged to measure controllable parameters of the drilling operation. As a non-limiting example, sensors may be arranged to measure weight-on-bit, drill rotational speed (RPM), flow rate of the mud pumps (GPM), and rate of penetration of the drilling operation (ROP). Each sensor may be positioned or configured to measure a desired physical stimulus. Drilling may be considered complete when a drilling target with the hydrocarbon reservoir 106 is reached or the presence of hydrocarbons is established.

Embodiments may be implemented on a computer system. FIG. 17 is a block diagram of a computer system (1700) used to provide computational functionalities associated with described algorithms, methods, functions, processes, flows, and procedures as described in the instant disclosure, according to an implementation. The illustrated computer system (1700) is intended to encompass any computing device such as a high performance computing (HPC) device, a server, desktop computer, laptop/notebook computer, wireless data port, smart phone, personal data assistant (PDA), tablet computing device, one or more processors within these devices, or any other suitable processing device, including both physical or virtual instances (or both) of the computing device. Additionally, the computer system (1700) may include a computer that includes an input device, such as a keypad, keyboard, touch screen, or other device that can accept user information, and an output device that conveys information associated with the operation of the computer system (1700), including digital data, visual, or audio information (or a combination of information), or a GUI.

The computer system (1700) can serve in a role as a client, network component, a server, a database or other persistency, or any other component (or a combination of roles) of a computer system for performing the subject matter described in the instant disclosure. The illustrated computer system (1700) is communicably coupled with a network (1702). In some implementations, one or more components of the computer system (1700) may be configured to operate within environments, including cloud-computing-based, local, global, or other environment (or a combination of environments).

At a high level, the computer system (1700) is an electronic computing device operable to receive, transmit, process, store, or manage data and information associated with the described subject matter. According to some implementations, the computer system (1700) may also include or be communicably coupled with an application server, e-mail server, web server, caching server, streaming data server, business intelligence (BI) server, or other server (or a combination of servers).

The computer system (1700) can receive requests over network (1702) from a client application (for example, executing on another computer system (1700)) and responding to the received requests by processing the said requests in an appropriate software application. In addition, requests may also be sent to the computer system (1700) from internal users (for example, from a command console or by other appropriate access method), external or third-parties, other automated applications, as well as any other appropriate entities, individuals, systems, or computers.

Each of the components of the computer system (1700) can communicate using a system bus (1704). In some implementations, any or all of the components of the computer system (1700), both hardware or software (or a combination of hardware and software), may interface with each other or the interface (1706) (or a combination of both) over the system bus (1704) using an application programming interface (API) (1708) or a service layer (1710) (or a combination of the API (1708) and service layer (1710). The API (1708) may include specifications for routines, data structures, and object classes. The API (1708) may be either computer-language independent or dependent and refer to a complete interface, a single function, or even a set of APIs. The service layer (1710) provides software services to the computer system (1700) or other components (whether or not illustrated) that are communicably coupled to the computer (1700). The functionality of the computer (1700) may be accessible for all service consumers using this service layer. Software services, such as those provided by the service layer (1710), provide reusable, defined business functionalities through a defined interface. For example, the interface may be software written in JAVA, C++, or other suitable language providing data in extensible markup language (XML) format or other suitable format. While illustrated as an integrated component of the computer (1700), alternative implementations may illustrate the API (1708) or the service layer (1710) as stand-alone components in relation to other components of the computer (1700) or other components (whether or not illustrated) that are communicably coupled to the computer (1700). Moreover, any or all parts of the API (1708) or the service layer (1710) may be implemented as child or sub-modules of another software module, enterprise application, or hardware module without departing from the scope of this disclosure.

The computer (1700) includes an interface (1706). Although illustrated as a single interface (1706) in FIG. 17, two or more interfaces (1706) may be used according to particular needs, desires, or particular implementations of the computer (1700). The interface (1706) is used by the computer (1700) for communicating with other systems in a distributed environment that are connected to the network (1702). Generally, the interface (1706) includes logic encoded in software or hardware (or a combination of software and hardware) and operable to communicate with the network (1702). More specifically, the interface (1706) may include software supporting one or more communication protocols associated with communications such that the network (1702) or interface's hardware is operable to communicate physical signals within and outside of the illustrated computer (1700).

The computer (1700) includes at least one computer processor (1712). Although illustrated as a single computer processor (1712) in FIG. 17, two or more processors may be used according to particular needs, desires, or particular implementations of the computer (1700). Generally, the computer processor (1712) executes instructions and manipulates data to perform the operations of the computer (1700) and any algorithms, methods, functions, processes, flows, and procedures as described in the instant disclosure.

The computer (1700) also includes a memory (1714) that holds data for the computer (1700) or other components (or a combination of both) that may be connected to the network (1702). For example, memory (1714) may be a database storing data consistent with this disclosure. Although illustrated as a single memory (1714) in FIG. 17, two or more memories may be used according to particular needs, desires, or particular implementations of the computer (1700) and the described functionality. While memory (1714) is illustrated as an integral component of the computer (1700), in alternative implementations, memory (1714) may be external to the computer (1700).

In addition to holding data, the memory may be a non-transitory medium storing computer readable instruction capable of execution by the computer processor (1712) and having the functionality for carrying out manipulation of the data including mathematical computations.

The application (1716) is an algorithmic software engine providing functionality according to particular needs, desires, or particular implementations of the computer (1700), particularly with respect to functionality described in this disclosure. For example, application (1716) can serve as one or more components, modules, applications, etc. Further, although illustrated as a single application (1716), the application (1716) may be implemented as multiple applications (1716) on the computer (1700). In addition, although illustrated as integral to the computer (1700), in alternative implementations, the application (1716) may be external to the computer (1700).

There may be any number of computers (1700) associated with, or external to, a computer system containing computer (1700), each computer (1700) communicating over network (1702). Further, the term “client,” “user,” and other appropriate terminology may be used interchangeably as appropriate without departing from the scope of this disclosure. Moreover, this disclosure contemplates that many users may use one computer (1700), or that one user may use multiple computers (1700).

In some embodiments, the computer (1700) is implemented as part of a cloud computing system. For example, a cloud computing system may include one or more remote servers along with various other cloud components, such as cloud storage units and edge servers. In particular, a cloud computing system may perform one or more computing operations without direct active management by a user device or local computer system. As such, a cloud computing system may have different functions distributed over multiple locations from a central server, which may be performed using one or more Internet connections. More specifically, cloud computing system may operate according to one or more service models, such as infrastructure as a service (IaaS), platform as a service (PaaS), software as a service (SaaS), mobile “backend” as a service (MBaaS), serverless computing, artificial intelligence (AI) as a service (AIaaS), and/or function as a service (FaaS).

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed is:

1. A method of generating a reservoir simulation grid for a subterranean reservoir, comprising:
using a reservoir simulation system:
obtaining a reservoir model, wherein the reservoir model comprises a plurality of wellbore trajectories,
defining a coarse simulation grid pertaining to, at least a portion, of the reservoir model,
determining a grid refinement field based, at least in part, on the reservoir model,
forming a tree based on the coarse simulation grid,
refining the tree at least in part, on an intersection of the grid refinement field and the coarse simulation grid, and
defining the reservoir simulation grid based, at least in part, on the refined tree and the coarse simulation grid.

2. The method of claim 1, further comprising performing a reservoir simulation using the reservoir simulation grid, wherein the reservoir simulation simulates fluid percolation within the subterranean reservoir over a plurality of fluid production time intervals.

3. The method of claim 2, further comprising altering a reservoir production operation based on the reservoir simulation.

4. The method of claim 3, wherein the reservoir production operation, guided by the reservoir simulation is selected from the group consisting of drilling, using a drilling system, a wellbore; changing, using a choke, a production rate of at least one well, and changing, using a pumping system, an injection rate of a stimulation fluid into at least one well.

5. The method of claim 1, wherein determining the grid refinement field is based, at least in part, on a spatial location of points in the field relative to perforation positions along the plurality of wellbore trajectories.

6. The method of claim 1, wherein refining the tree comprises:
forming a larger tree by adding leaves to the tree based, at least in part, on the grid refinement field; and
deleting leaves on the larger tree based on refinement factors of adjacent leaves.

7. The method of claim 6, further comprising updating the grid refinement field based, at least in part, on a geometry of the larger tree.

8. The method of claim 1, further comprising:
using the reservoir simulation system:
updating the grid refinement field based, at least in part, on a result of the reservoir simulation, wherein the reservoir simulation simulates fluid percolation within the subterranean reservoir over a plurality of fluid production time intervals
refining the tree based, at least in part, on the intersection of the updated grid refinement field and the coarse simulation grid,
updating the reservoir simulation grid based, at least in part, on the refined tree and the coarse simulation grid, and
performing an updated reservoir simulation using the updated reservoir simulation grid, wherein the updated reservoir simulation simulates fluid percolation within the subterranean reservoir over a fluid production time interval later than the fluid production time intervals in the plurality of fluid production time intervals.

9. The method of claim 8, further comprising:
using the reservoir simulation system:
correcting the grid refinement field based, at least in part, on a difference between a fluid production rate predicted by the reservoir simulation at a simulated production time and an observed fluid production rate,
correcting the tree based, at least in part, on the intersection of the corrected grid refinement field and the coarse simulation grid,
correcting the reservoir simulation grid based, at least in part, on the corrected tree and the coarse simulation grid, and
performing a repeated reservoir simulation using the corrected reservoir simulation grid, wherein the repeated reservoir simulation simulates fluid percolation within the subterranean reservoir over a fluid production time interval selected from the plurality of fluid production time intervals.

10. The method of claim 1, wherein forming a tree comprises forming an octree.

11. A system, comprising:
a reservoir model pertaining to a subterranean reservoir, wherein the reservoir model comprises a plurality of wellbore trajectories; and
a reservoir simulation system, configured to:
receive the reservoir model,
define a coarse simulation grid pertaining to, at least a portion, of the reservoir model,
determine a grid refinement field based, at least in part, on the reservoir model,
form a tree based on the coarse simulation grid,
refine the tree at least in part, on an intersection of the grid refinement field and the coarse simulation grid, and
define the reservoir simulation grid based, at least in part, on the refined tree and the coarse simulation grid.

12. The system of claim 11, further configured to perform a reservoir simulation using the reservoir simulation grid, wherein the reservoir simulation simulates fluid percolation within the subterranean reservoir over a plurality of fluid production time intervals.

13. The system of claim 11, further comprising a wellbore planning system configured to plan a planned wellbore trajectory based, at least in part on a result of the reservoir simulation.

14. The system of claim 13, further comprising a drilling system configured to drill a wellbore guided by planned wellbore trajectory.

15. The system of claim 12, further comprising a pumping system, configured to pump a stimulation fluid into at least one well guided by a result of the reservoir simulation.

16. The system of claim 11, wherein the grid refinement field is based, at least in part, on a spatial location of points in the field relative to perforation positions along the plurality of wellbore trajectories.

17. The system of claim 11, wherein refining the tree comprises:
forming a larger tree by adding leaves to the tree based, at least in part, on the grid refinement field; and
deleting leaves on the larger tree based on refinement factors of adjacent leaves.

18. The system of claim 17, wherein the reservoir simulation system is further configured to update the grid refinement field based, at least in part, on a geometry of the larger tree.

19. The system of claim 11, wherein the reservoir simulation system is further configured to:
update the grid refinement field based, at least in part, on a result of the reservoir simulation, wherein the reservoir simulation simulates fluid percolation within the subterranean reservoir over a plurality of fluid production time intervals
refine the tree based, at least in part, on the intersection of the updated grid refinement field and the coarse simulation grid,
update the reservoir simulation grid based, at least in part, on the refined tree and the coarse simulation grid, and
perform an updated reservoir simulation using the updated reservoir simulation grid, wherein the updated reservoir simulation simulates fluid percolation within the subterranean reservoir over a fluid production time interval later than the fluid production time intervals in the plurality of fluid production time intervals.

20. The system of claim 19, wherein the reservoir simulation system is further configured to:
correct the grid refinement field based, at least in part, on a difference between a fluid production rate predicted by the reservoir simulation and an observed fluid production rate,
correct the tree based, at least in part, on the intersection of the corrected grid refinement field and the coarse simulation grid,
correct the reservoir simulation grid based, at least in part, on the corrected tree and the coarse simulation grid, and
perform a repeated reservoir simulation using the corrected reservoir simulation grid, wherein the repeated reservoir simulation simulates fluid percolation within the subterranean reservoir over a fluid production time interval selected from the plurality of fluid production time intervals.
